(19) United States
(12) Patent Application Publication
(10) Pub. No.: US 2025/0118588 A1
(43) Pub. Date: Apr. 10, 2025

(54) DISPLAY DEVICE, MANUFACTURING EQUIPMENT OF DISPLAY DEVICE, AND MANUFACTURING METHOD OF DISPLAY DEVICE

(71) Applicant: Samsung Display Co., LTD., Yongin-si (KR)

(72) Inventors: Dong Jun LEE, Yongin-si (KR); Byoung Yong KIM, Yongin-si (KR)

(21) Appl. No.: 18/652,583

(22) Filed: May 1, 2024

(30) Foreign Application Priority Data
Oct. 4, 2023 (KR) 10-2023-0131978

(51) Int. Cl. H01L 21/683; H01L 25/075; H01L 33/62

(52) U.S. Cl. CPC H01L 21/6835; H01L 25/0753; H10H 20/857; H01L 2221/68354; H01L 2221/68363; H10H 20/0364

(57) ABSTRACT

A method of manufacturing a display device includes: grouping light emitting elements formed on a first substrate based on a light emission characteristic; and transferring the light emitting elements onto a second substrate such that the light emitting elements grouped as the same group are located adjacent to each other.

### CROSS-REFERENCE TO RELATED APPLICATION

The present application claims priority to and the benefit of Korean Patent Application No. 10-2023-0131978, filed on Oct. 4, 2023, in the Korean Intellectual Property Office, the entire disclosure of which is incorporated herein by reference.

### BACKGROUND

### 1. Field

Aspects of embodiments of the present disclosure relate to a display device, a manufacturing equipment of a display device, and a manufacturing method of a display device.

### 2. Description of the Related Art

A display panel may include light emitting elements. The display panel may be manufactured by transferring and bonding the light emitting elements onto a substrate on which transistors are formed.

Even when light emitting elements are manufactured on the same substrate, a deviation occurs in a light emission characteristic of the light emitting elements (e.g., an intensity or chromaticity of light) due to minute differences in material mixing ratio. In a display device manufactured by transferring the light emitting elements (or in an image displayed by such a display device), Mura occurs due to the deviation in the light emission characteristics of the light emitting elements.

### SUMMARY

Embodiments of the present disclosure provide a display device and a manufacturing method of a display device which prevents Mura (e.g., which prevents inconsistency in display characteristics at different areas of the display device).

According to an embodiment of the present disclosure, a method of manufacturing a display device includes: grouping light emitting elements formed on a first substrate based on a light emission characteristic; and transferring the light emitting elements onto a second substrate such that the light emitting elements grouped as the same group are located adjacent to each other.

The grouping of the light emitting elements may include: dividing the light emitting elements on the first substrate into a plurality of blocks based on positions; and grouping the blocks based on the light emission characteristic. The transferring of the light emitting elements onto the second substrate may include transferring the light emitting elements in a block unit onto the second substrate such that blocks in the same group from among the blocks are located adjacent to each other.

The light emission characteristic may be an average wavelength of light emitted from light emitting elements in each of the blocks.

In the transferring of the light emitting elements onto the second substrate, the light emitting elements may be transferred such as the light emission characteristic gradually changes along a first direction on the second substrate.

Light emitting elements arranged along a second direction perpendicular to the first direction on the second substrate may have the same light emission characteristic.

The second substrate may have a first area, a second area, and a third area, which are sequentially arranged along the first direction. The blocks grouped as a first group may be transferred to the first area, the blocks grouped as a second group may be transferred to the second area, and the blocks grouped as a third group may be transferred to the third area.

The method may further include successively connecting a first sub-panel and a second sub-panel, each of which includes the light emitting elements on the second substrate. The light emitting elements having the same light emission characteristic may be disposed at a first edge of the first sub-panel and a second edge of the second sub-panel, which are connected to each other.

Groups into which the light emitting elements are grouped may include a first group and a second group. The second substrate may have a first area and a second area, which are sequentially arranged along a first direction. The light emitting elements in the first group may be arranged in the first area of the second substrate, and the light emitting elements in the second group may be arranged in the second area of the second substrate. The light emitting elements in the first group and the second group may be mixed and arranged in a boundary area between the first area and the second area.

The transferring of the light emitting elements onto the second substrate may include: transferring the light emitting elements to the first and second areas of the second substrate in a first block unit having a first size; and transferring the light emitting elements to the boundary area of the second substrate in a second block unit having a second size smaller than the first size.

The method may further include transferring light emitting elements formed on a third substrate different from the first substrate onto the second substrate such that the light emitting elements having similar or the same light emission characteristics are located adjacent to each other.

According to another embodiment of the present disclosure, an equipment for manufacturing a display device includes: a control unit configured to group light emitting elements formed on a first substrate based on a light emission characteristic and to generate mapping information by mapping positions of the light emitting elements on the first substrate to positions at which the light emitting elements are to be transferred onto a second substrate such that the light emitting elements grouped as the same group are located adjacent to each other on the second substrate; and a transfer unit configured to transfer the light emitting elements from the first substrate onto the second substrate based on the mapping information.

The control unit may be configured to divide the light emitting elements on the first substrate into a plurality of blocks based on positions, to group the blocks based on the light emission characteristic, and to generate the mapping information such that the blocks grouped as the same group are located adjacent to each other.

The light emission characteristic may be an average wavelength of light emitted from light emitting elements in each of the blocks.

The control unit may be configured to generate the mapping information such that the light emission characteristic gradually changes along a first direction on the second substrate. Light emitting elements arranged along a second direction perpendicular to the first direction on the second substrate may have the same light emission characteristic.

The second substrate may have a first area, a second area, and a third area, which are sequentially arranged along the first direction. The transfer unit may be configured to transfer the blocks grouped as a first group to the first area, to transfer the blocks grouped as a second group to the second area, and to transfer the blocks grouped as a third group to the third area.

According to another embodiment of the present disclosure, a display device includes light emitting elements arranged on a substrate. The light emitting elements are grouped based on a light emission characteristic, and the light emitting elements grouped as the same group are located adjacent to each other.

The light emission characteristic of the light emitting elements may gradually change along a first direction. Light emitting elements arranged along a second direction perpendicular to the first direction may have the same light emission characteristic.

The substrate may have a first area, a second area, and a third area, which are sequentially arranged along the first direction. The light emitting elements having a first light emission characteristic may be arranged in the first area, the light emitting elements having a second light emission characteristic may be arranged in the second area, and the light emitting elements having a third light emission characteristic may be arranged in the third area. The first light emission characteristic, the second light emission characteristic, and the third light emission characteristic may be different from one another.

The light emitting elements having the first light emission characteristic and the light emitting elements having the second light emission characteristic may be mixed and arranged in a boundary area between the first area and the second area.

The display device may further include a first sub-panel and a second sub-panel, each including the light emitting elements on the substrate. The first sub-panel and the second sub-panel may be successively connected to each other. The light emitting elements having the same light emission characteristic may be arranged at a first edge of the first sub-panel and a second edge of the second sub-panel, which are connected to each other.

### BRIEF DESCRIPTION OF THE DRAWINGS

Embodiments of the present disclosure will now be described more fully hereinafter with reference to the accompanying drawings; however, the present disclosure may be embodied in different forms and should not be construed as limited to the embodiments set forth herein. Rather, these embodiments are provided so that this disclosure will be thorough and complete and will fully convey the scope of the present disclosure to those skilled in the art.

FIG. 1 is a plan view illustrating a display device according to an embodiment of the present disclosure.

FIG. 2 is a plan view illustrating an embodiment of a pixel of the display device shown in FIG. 1.

FIG. 3 is a cross-sectional view of the display device shown in FIG. 1.

FIG. 4 is a plan view illustrating a display device according to an embodiment of the present disclosure.

FIG. 5 is a schematic diagram illustrating a manufacturing equipment to manufacture a display device according to an embodiment of the present disclosure.

FIG. 6 is a flowchart describing a manufacturing method of a display device according to an embodiment of the present disclosure.

FIG. 7 is an image illustrating an example of a light emission characteristic of light emitting elements of a first substrate.

FIG. 8 is an illustration of an example in which light emitting elements of a first substrate are divided into blocks.

FIG. 9 is an illustration of an example in which the blocks shown in FIG. 8 are grouped.

FIG. 10 is an illustration of an example in which the light emitting elements of the first substrate are mapped to a second substrate in a block unit.

FIG. 11 is a diagram illustrating an example in which light emitting elements are transferred in a block unit.

FIG. 12 is an illustration of a display device according to a comparative example.

FIG. 13 is a plan view illustrating a display device according to an embodiment of the present disclosure.

FIG. 14 is a plan view illustrating a display device according to an embodiment of the present disclosure.

FIG. 15 is a plan view illustrating a display device according to an embodiment of the present disclosure.

FIG. 16 is a plan view illustrating a display device according to an embodiment of the present disclosure.

FIG. 17 is a plan view illustrating a display device according to an embodiment of the present disclosure.

### DETAILED DESCRIPTION

The described embodiments may be variously changed and may have different shapes, therefore the described embodiments only illustrate details with respect to particular non-limiting examples. In other words, the described embodiments are not limited to certain shapes but include all the changes and equivalent materials and replacements. The drawings included are illustrated in a fashion where the figures are expanded for the better understanding.

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the present disclosure. As used herein, the singular forms are intended to include the plural forms as well, unless the context clearly indicates otherwise.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be further understood that the terms “includes” and/or “including,” when used in this specification, specify the presence of stated features, integers, steps, operations, elements, and/or components, but do not preclude the presence and/or addition of one or more other features, integers, steps, operations, elements, components, and/or groups thereof. Further, an expression that an element such as a layer, region, substrate or plate is placed “on” or “above” another element indicates not only a case where the element is placed “directly on” or “just above” the other element but also a case where a further element is interposed between the element and the other element. On the contrary, an expression that an element such as a layer, region, substrate or plate is placed “beneath” or “below” another element indicates not only a case where the element is placed “directly beneath” or “just below” the other element but also a case where a further element is interposed between the element and the other element.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

Aspects and features of the present disclosure and a method of achieving them will be made clear by referring to the embodiments described below in detail together with the accompanying drawings. However, the present disclosure is not limited to the embodiments disclosed herein but may be implemented in various forms. In the entire specification, when an element is referred to as being “connected” or “coupled” to another element, it can be directly connected or coupled to the other element or be electrically connected or coupled to the other element with one or more intervening elements interposed therebetween. The term “connection” between two components may include both electrical connection and physical connection.

Hereinafter, a display device according to embodiments of the present disclosure will be described with reference to the accompanying drawings.

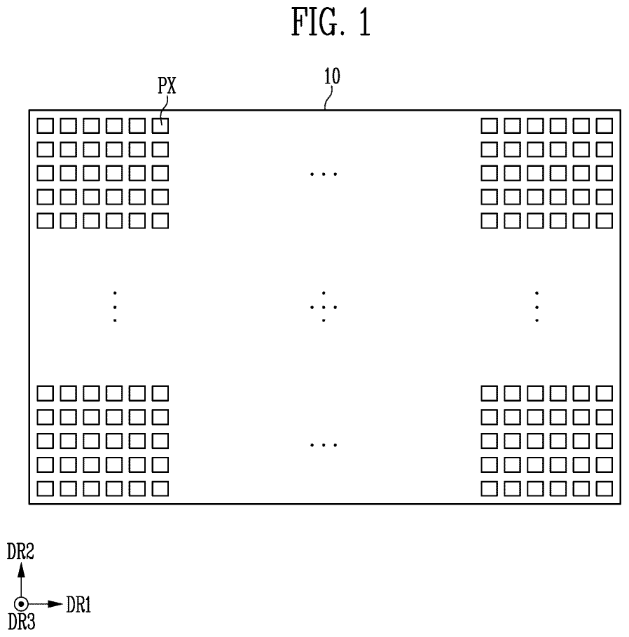

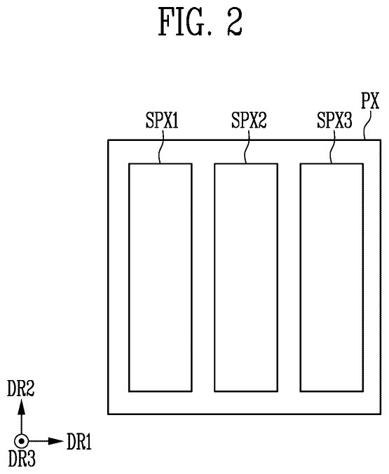

FIG. 1 is a plan view illustrating a display device according to an embodiment of the present disclosure. FIG. 2 is a plan view illustrating an embodiment of a pixel of the display device shown in FIG. 1.

Referring to FIG. 1, the display device 10 (or a display panel) may be configured to output optical information (e.g., to display an image). For example, the display device 10 is a device that displays moving images and/or still images and may be applied to (or may be included in) various devices. The display device 10 may have a rectangular plane shape having long sides in a first direction DR1 and short sides in a second direction DR2 crossing (e.g., intersecting) the first direction DR1. A corner at where the long side in the first direction DR1 and the short side in the second direction DR2 meet each other may be formed round to have a curvature (e.g., a predetermined curvature) or may be formed at a right angle. The planar shape of the display device 10 is not limited to a quadrangular shape, and the display device 10 may have another polygonal shape, a circular shape, or an elliptical shape. The display device 10 may be formed flat, but the present disclosure is not limited thereto. For example, the display device 10 may include a curved portion which is formed at a left/right end and has a constant curvature or a varying (or changing) curvature. In addition, the display device 10 may be flexible enough to be warpable, curvable, bendable, foldable or rollable.

The display device 10 may include pixels PX to display images. The pixel PX may be a minimum unit for displaying full-color light. The pixels PX may be arranged in a matrix form in the first direction DR1 and the second direction DR2.

Each of the pixels PX may include a plurality of sub-pixels SPX1 to SPX3. In FIG. 2, an embodiment in which the pixel PX includes three sub-pixels SPX1 to SPX3, i.e., a first sub-pixel SPX1, a second sub-pixel SPX2, and a third sub-pixel SPX3, is illustrated. However, the present disclosure is not limited thereto.

Each of the first sub-pixel SPX1, the second sub-pixel SPX2, and the third sub-pixel SPX3 may have a rectangular, square, or rhombic planar shape. For example, each of the first sub-pixel SPX1, the second sub-pixel SPX2, and the third sub-pixel SPX3 may have a rectangular planar shape having short sides in the first direction DR1 and long sides in the second direction DR2, as shown in, for example, FIG. 2. In other embodiments, each of the first sub-pixel SPX1, the second sub-pixel SPX2, and the third sub-pixel SPX3 may have a square or rhombic planar shape including sides having the same length in the first direction DR1 and the second direction DR2.

As shown in FIG. 2, the first sub-pixel SPX1, the second sub-pixel SPX2, and the third sub-pixel SPX3 may be arranged in (e.g., may be adjacent to each other in) the first direction DR1. However, the arrangement of the sub-pixels SPX1 to SPX3 is not limited thereto. For example, any one of the second sub-pixel SPX2 and the third sub-pixel SPX3 and the first sub-pixel SPX1 may be arranged in the first direction DR1, and the other of the second sub-pixel SPX2 and the third sub-pixel SPX3 and the first sub-pixel SPX1 may be arranged in the second direction DR2.

The first sub-pixel SPX1 may emit first light, the second sub-pixel SPX2 may emit second light, and the third sub-pixel SPX3 may emit third light. The first light may be light in a red wavelength band, the second light may be light in a green wavelength band, and the third light may be light in a blue wavelength band. The red wavelength band may be a wavelength band in a range of about 600 nm to about 750 nm, the green wavelength band may be a wavelength band in a range of about 480 nm to about 560 nm, and the blue wavelength band may be a wavelength band in a range of about 370 nm to about 460 nm. However, the present disclosure is not limited thereto.

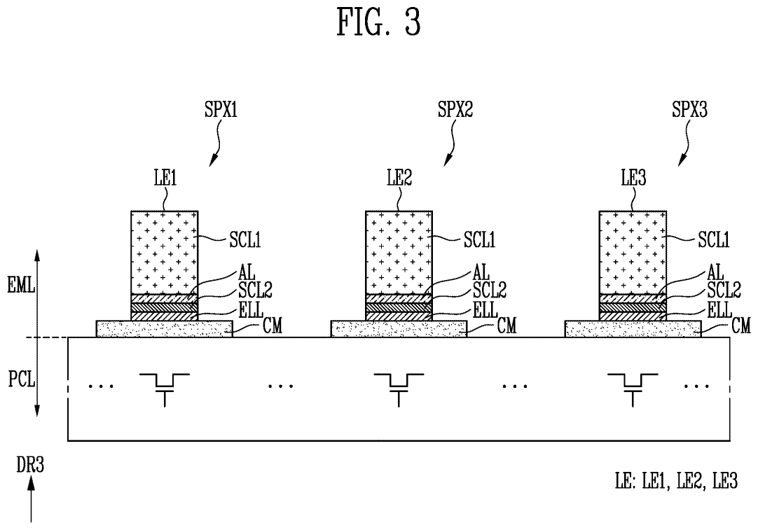

Each of the first sub-pixel SPX1, the second sub-pixel SPX2, and the third sub-pixel SPX3 may include an inorganic light emitting element having an inorganic semiconductor as a light emitting element LE (see, e.g., FIG. 3) for emitting light.

As shown in FIG. 2, an area of the first sub-pixel SPX1, an area of the second sub-pixel SPX2, and an area of the third sub-pixel SPX3 may be substantially the same, but the present disclosure is not limited thereto. At least one of the area of the first sub-pixel SPX1, the area of the second sub-pixel SPX2, and the area of the third sub-pixel SPX3 may be different from another of the area of the first sub-pixel SPX1, the area of the second sub-pixel SPX2, and the area of the third sub-pixel SPX3.

FIG. 3 is a cross-sectional view illustrating aspects of the display device shown in FIG. 1. In FIG. 3, the cross-sectional view of the display device is schematically illustrated based on one pixel PX.

Referring to FIG. 3, the display device 10 may include a pixel circuit layer PCL and a light emitting element layer EML.

The pixel circuit layer PCL may be a layer including pixel circuits for driving light emitting elements LE. The pixel circuit layer PCL may include a substrate, metal layers for forming the pixel circuits, and insulating layers disposed between the metal layers. The substrate may be a base substrate or a base member, which is used to support the display device 10. The substrate may be a rigid substrate made of a glass material. In another embodiment, the substrate may be a flexible substrate, which is bendable, foldable, rollable, and the like. The substrate may include an insulating material including polymer resin, such as polyimide. In some embodiments, the pixel circuits may include at least one transistor. The pixel circuits may further include a storage capacitor. The pixel circuits may be electrically connected to the light emitting elements LE to provide an electrical signal for allowing the light emitting elements LE to emit light.

The light emitting element layer EML may be disposed on the pixel circuit layer PCL. The light emitting element layer EML may include a first electrode CM and light emitting elements LE.

The first electrode CM may be disposed on the pixel circuit layer PCL. The first electrode CM may be disposed on the bottom of each of the light emitting elements LE to be electrically connected to the light emitting element LE. The first electrode CM may be electrically connected to the pixel circuit (e.g., a driving transistor and the like) formed in the pixel circuit layer PCL. Accordingly, the first electrode CM may receive an electrical signal (e.g., a driving signal as an anode signal) for driving the light emitting elements LE. The electrical signal may be applied to each of the light emitting elements LE through an electrical contact surface between the light emitting element LE and the first electrode CM.

The first electrode CM may include a conductive material. For example, the first electrode CM may include at least one selected from the group consisting of silver (Ag), magnesium (Mg), aluminum (AI), platinum (Pt), palladium (Pd), gold (Au), nickel (Ni), neodymium (Nd), iridium (Ir), chromium (Cr), and titanium (Ti). In some embodiments, the first electrode CM may include at least one selected from the group consisting of indium tin oxide (ITO), indium zinc oxide (IZO), zinc oxide (ZnO), indium gallium zinc oxide (IGZO), or indium tin zinc oxide (ITZO), and a conductive polymer, such as poly (3,4-ethylenedioxythiophene) (PEDOT). However, the present disclosure is not limited to the above-described examples.

The light emitting elements LE may be disposed on the first electrode CM to be electrically connected to the first electrode CM. The light emitting element LE may be provided in each of sub-pixels SPX1, SPX2, and SPX3. For example, a first light emitting element LE1 may be provided in a first sub-pixel SPX1, a second light emitting element LE2 may be provided in a second sub-pixel SPX2, and a third light emitting element LE3 may be provided in a third sub-pixel SPX3.

The light emitting element LE may be configured to emit light. For example, the first light emitting element LE1 may emit first light, the second light emitting element LE2 may emit second light, and the third light emitting element LE3 may emit third light. In another embodiment, the first, second, and third light emitting elements LE1, LE2, and LE3 may emit the same light (e.g., the third light). A light conversion element (e.g., a quantum dot) for converting the wavelength of light (e.g., for converting the third light into the first light or the second light) may be disposed on (or above) some of the first, second, and third light emitting elements LE1, LE2, and LE3.

The light emitting element LE may include a first semiconductor layer SCL1, a second semiconductor layer SCL2, and an active layer AL disposed between the first semiconductor layer SCL1 and the second semiconductor layer SCL2. In some embodiments, the light emitting element LE may further include an electrode layer ELL. The light emitting element LE may have various shapes. For example, the light emitting element LE may have a pillar shape extending in one direction. However, the present disclosure is not limited to the above-described example.

The light emitting element LE may have various sizes. For example, the light emitting element LE may a size of micro scale to nano scale. For example, the light emitting element LE may have a size in a range of about 5 um to about 100 um. However, the size of the light emitting element LE is not limited to a specific numerical value range.

The first semiconductor layer SCL1 may include a first conductivity type semiconductor. The first semiconductor layer SCL1 may be disposed on the active layer AL and may include a semiconductor layer having a type different from that of the second semiconductor layer SCL2. For example, the first semiconductor layer SCL1 may include an n-type semiconductor. For example, the first semiconductor layer SCL1 may include at least one selected from the group consisting of InAlGaN, GaN, AlGaN, InGaN, AlN, and InN and may include an n-type semiconductor layer doped with a first conductivity type dopant, such as Si, Ge, or Sn. However, the present disclosure is not limited to the above-described example. The first semiconductor layer SCL1 may include various materials.

The active layer AL may be disposed between the first semiconductor layer SCL1 and the second semiconductor layer SCL2. The active layer AL may include (or may have) a single-quantum well structure or a multi-quantum well structure. The position of the active layer AL is not limited and may be variously changed according to the kind of the light emitting element LE.

A clad layer doped with a conductive dopant may be formed at one side and/or another side of the active layer AL. For example, the clad layer may include at least one of AlGaN and InAlGaN. However, the present disclosure is not limited to the above-described example.

The second semiconductor layer SCL2 may include a second conductivity type semiconductor. The second semiconductor layer SCL2 may be disposed on the bottom of the active layer AL and may include a semiconductor layer having a type different from that of the first semiconductor layer SCL1. For example, the second semiconductor layer SCL2 may include a p-type semiconductor layer. For example, the second semiconductor layer SCL2 may include at least one selected from the group consisting of InAlGaN, GaN, AlGaN, InGaN, AlN, and InN, and may include a p-type semiconductor layer doped with a second conductivity type dopant, such as Ga, B, or Mg. However, the present disclosure is not limited to the above-described example. The second semiconductor layer SCL2 may include various materials.

When a voltage which is a threshold voltage or higher is applied to the light emitting element LE, electron-hole pairs may be combined in the active layer AL, and the light emitting element LE may emit light. The light emission of the light emitting element LE is controlled by using such a principle, so that the light emitting element LE can be used as a light source for various devices.

The electrode layer ELL may be disposed on the bottom of the second semiconductor layer SCL2. The electrode layer ELL may be in contact with the first electrode CM. In one embodiment, the electrode layer ELL may include at least one selected from the group consisting of chromium (Cr), titanium (Ti), aluminum (AI), gold

(Au), nickel (Ni), oxides thereof, and alloys thereof. However, the present disclosure is not limited to the above-described examples.

The first electrode CM may be a bonding electrode. The light emitting element LE may be bonded and coupled to the first electrode CM. For example, the light emitting element LE may be transferred on the first electrode CM by using various transfer methods, may be bonded to the first electrode CM by using one bonding method, and may be electrically connected to the first electrode CM. A laser transfer method, a stamp transfer method, and the like may be used as the transfer methods. The bonding method may include an anisotropic conductive film (AFC) bonding method, a laser assist bonding (LAB) method using a laser, an ultrasonic bonding method, a bump-ball surface mounting method (e.g., using ball grid array (BGA)), a thermal compression (TC) bonding method, and the like.

The stacked structure of the display device 10 is not limited to the above-described example. In some embodiments, the display device 10 may further include additional layers (e.g., a color filter, an outer film, and the like).

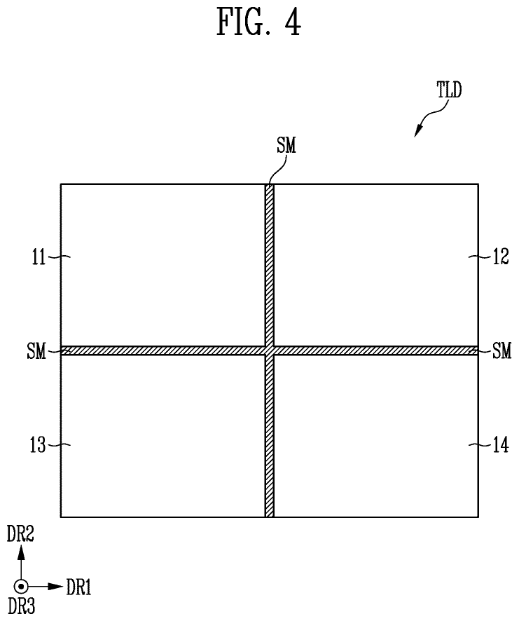

FIG. 4 is a plan view illustrating a display device according to an embodiment of the present disclosure. In FIG. 4, a tiled display device TLD including a plurality of display devices (or display panels) is illustrated as an embodiment of the display device.

Referring to FIGS. 1 and 4, the tiled display device TLD may include display devices 11 to 14 and a seam SM. For example, the tiled display device TLD may include a first display device 11, a second display device 12, a third display device 13, and a fourth display device 14.

The display devices 11 to 14 may be arranged in a lattice arrangement. The display devices 11 to 14 may be arranged in a matrix form having M (M is an integer of 1 or more) rows and N (N is an integer of 1 or more) columns. For example, the first display device 11 and the second display device 12 may be adjacent to each other in the first direction DR1. The first display device 11 and the third display device 13 may be adjacent to each other in the second direction DR2. The third display device 13 and the fourth display device 14 may be adjacent to each other in the first direction DR1. The second display device 12 and the fourth display device 14 may be adjacent to each other in the second direction DR2.

However, the number and arrangement of the display devices 11 to 14 in the tiled display device TLD are not limited to those shown in FIG. 4. The number and arrangement of the display devices 11 to 14 included in the tiled display device TLD may be differently set according to a size of each of the display devices 11 to 14 and a size of the tiled display device TLD, a shape of the tiled display device TLD, and the like.

In FIG. 4, an embodiment in which the display devices 11 to 14 have the same size is illustrated. However, the present disclosure is not limited thereto. For example, at least one display device from among the display devices 11 to 14 may have a size different from a size of the other display devices.

Each of the display devices 11 to 14 may have a rectangular shape having long sides and short sides. The display devices 11 to 14 may be disposed such that long sides or short sides are connected to (or contact) each other. Some or all of the display devices 11 to 14 may be disposed at an edge of the tiled display device TLD and may form one side of the tiled display device TLD. At least one display device from among the display devices 11 to 14 may be disposed at at least one corner of the tiled display device TLD and may form two adjacent sides of the tiled display device TLD. At least one display device from among the display devices 11 to 14 may be surrounded by (e.g., surrounded in a plan view by) other display devices.

Each of the display devices 11 to 14 may be substantially identical to the display device 10 (see, e.g., FIG. 1) described in conjunction with FIGS. 1 to 4. Therefore, descriptions of each of the display devices 11 to 14 will be omitted.

The seam SM may include a coupling member or an adhesive member. The display devices 11 to 14 may be connected to each other through the coupling member or the adhesive member of the seam SM. The seam SM may be disposed between the first display device 11 and the second display device 12, between the first display device 11 and the third display device 13, between the second display device 12 and the fourth display device 14, and between the third display device 13 and the fourth display device 14.

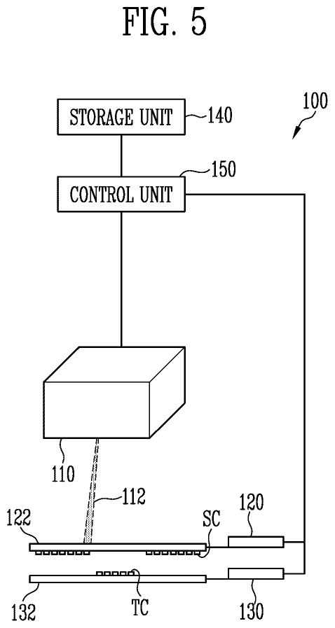

FIG. 5 is a view illustrating manufacturing equipment for manufacturing a display device according to an embodiment of the present disclosure. In FIG. 5, a transfer system 100 is illustrated as an embodiment of the manufacturing equipment.

Referring to FIG. 5, the transfer system 100 may transfer light emitting elements SC of a first substrate 122 (e.g., a source substrate) onto a second substrate 132 (e.g., a target substrate). Each of the light emitting elements SC may be the light emitting element LE shown in, for example, FIG. 3. For example, each of the light emitting elements SC may be a micro LED chip, but the present disclosure is not limited thereto.

The transfer system 100 may include a transfer unit 110 (or transfer device), a transport unit (or transport device or transporter), a storage unit 140 (or storage device or memory), a control unit 150 (or control device or controller). The transport unit may include stages 120 and 130.

The light emitting elements SC may be formed on the first substrate 122. In one embodiment, the light emitting elements SC may be arranged in a square or rectangular shape (or pattern) on the first substrate 122. However, the shape (or pattern) of the light emitting elements SC is not limited thereto, and the light emitting elements SC may be arranged in various shapes including a circular shape and a polygonal shape on the first substrate 122.

The second substrate 132 may receive the light emitting elements SC to be transferred thereon from the first substrate 122. To this end, the second substrate 132 may be located to (or arranged to) face the first substrate 122. The light emitting elements SC of the first substrate 122 may be transferred onto the second substrate 132 by an operation of (e.g., by using) the transfer unit 110.

The transfer unit 110 may transfer the light emitting elements SC from the first substrate 122 onto the second substrate 132 based on mapping information. The mapping information may be information in which positions of the light emitting elements SC on the first substrate 122 are mapped to positions at which the light emitting elements SC are to be transferred onto the second substrate 132 (e.g., positions of transferred light emitting elements TC on the second substrate 132). For example, the mapping information may be generated in (or generated by) the control unit 150 and may be stored in the form of a lookup table in the storage unit 140. However, the present disclosure is not limited thereto.

In an embodiment, the transfer unit 110 (or the transfer system 100) may be a laser transfer device. The transfer unit 110 may include a laser generator for generating laser light and a laser irradiation device for irradiating laser light at (or onto) a desired position in a desired direction, and the laser irradiation device may include a mirror, a lens, a scanner, and the like. For example, the light emitting elements SC formed on the first substrate 122 may be transferred onto the second substrate 132 by a laser beam 112 irradiated from the transfer unit 110 onto the first substrate 122.

In the illustrated embodiment, the transfer unit 110 (or the transfer system 100) is shown as a laser transfer device, but the transfer unit 110 is not limited thereto. For example, the transfer unit 110 (or the transfer system 100) may be implemented as a stamp transfer device, a roll transfer device, or the like. That is, the kind (or transfer method) of the transfer unit 110 is not limited as long as the transfer unit 110 can transfer the light emitting elements SC from the first substrate 122 onto the second substrate 132.

A first stage 120 may move the first substrate 122 under the control of the control unit 150 (e.g., the control unit 150 may control the movement of the first substrate 122 by controlling the movement of the first stage 120). In an embodiment, the first stage 120 may move the first substrate 122 in X-axis and Y-axis directions on a plane (e.g., may implement two-axis driving).

A second stage 130 may move the second substrate 132 under the control of the control unit 150 (e.g., the control unit 150 may control the movement of the second substrate 132 by controlling the movement of the second stage 130). The second stage 130 may move the second substrate 132 in X-axis and Y-axis directions on a plane. The control unit 150 may allow (or may control) each of the first substrate 122 and the second substrate 132 to be moved to a desired position by independently controlling the first stage 120 and the second stage 130.

The storage unit 140 may store the mapping information. Also, the storage unit 140 may store setting information, and the like, which are necessary for an operation of the transfer system 100.

The control unit 150 may control the transfer unit 110 and the transport unit (or the stages 120 and 130). For example, the control unit 150 may control the transfer unit 110 such that the laser beam 112 can be irradiated at a desired position. For example, the controller 150 may control the stages 120 and 130 such that each of the first substrate 122 and the second substrate 132 is located at (or is arranged at) a desired position.

In embodiments, the controller 150 may group (or grade) the light emitting elements SC formed on the first substrate 122 based on a light emission characteristic. For example, the light emission characteristic may be a wavelength (or average wavelength) of light emitted from the light emitting elements SC. As another example, the light emission characteristic may be an intensity of light emitted from the light emitting elements SC under the same driving conditions.

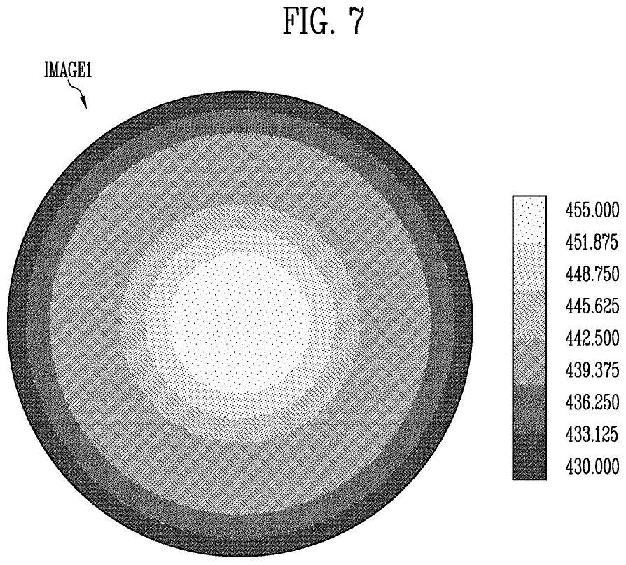

In an embodiment, the control unit 150 may divide the light emitting elements SC into a plurality of blocks, based on positions, and may group the blocks based on a light emission characteristic. Each of the blocks may correspond to a transfer unit (or a size of a transfer array) in which light emitting elements SC can be transferred at a time and may include at least one light emitting element. The light emission characteristic may be an average wavelength of light emitted from each block. An example in which the blocks are grouped based on the light emission characteristic will be described in more detail later with reference to FIGS. 7 to 9.

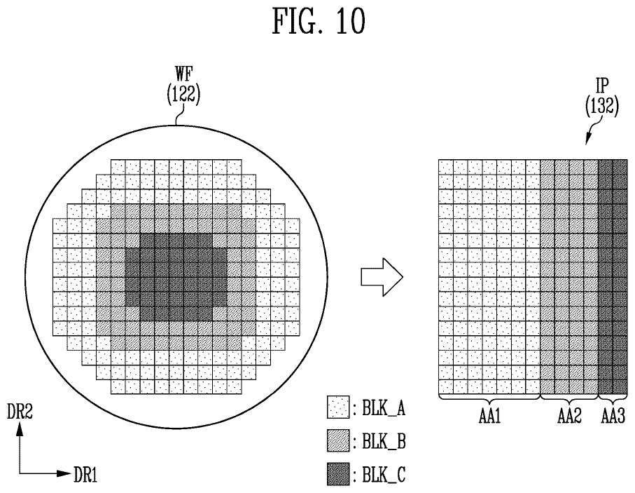

In an embodiment, the controller 150 may generate mapping information by mapping positions of the light emitting elements SC on the first substrate 122 to positions at where the light emitting elements SC are to be transferred onto the second substrate 132 (e.g., positions of transferred light emitting elements TC on the second substrate 132) such that light emitting elements SC grouped as the same group are located adjacent to each other on the second substrate 132. When the transfer is performed in a block unit, the controller unit 150 may generate the mapping information such that blocks grouped as the same group are located adjacent to each other. For example, the control unit 150 may generate the mapping information such that the light emitting elements SC of the first substrate 122 are not transferred onto the second substrate 132 in an arbitrary order (or randomly), but rather light emitting elements SC having the same light emission characteristic or having similar light emission characteristics are gathered and located on the second substrate 132. The mapping information will be described in more detail later with reference to FIG. 10.

When light emitting elements SC having the same light emission characteristic or having similar light emission characteristics are gathered and located on the second substrate 132, for example, when light emitting elements SC having the same light emission characteristic or having similar light emission characteristics are gathered and disposed in a specific area in the display device 10 (see, e.g., FIG. 1), Mura (or Mura phenomenon) caused by a deviation in the light emission characteristic does not occur in the display device 10. In addition, when light emitting elements SC having the same light emission characteristic or having similar light emission characteristics are gathered and disposed in a specific area of the display device 10, the same correction value or the same compensation value can be applied to the entire corresponding area to correct or compensate for the light emission characteristic of the light emitting elements SC. For example, when an image displayed by the display device 10 is corrected, a characteristic deviation of the light emitting elements SC need not be considered and image correction of the display device 10 can be readily performed.

The control unit 150 may be physically implemented by a logic circuit, an individual component, a microprocessor, a hard wire circuit, a memory element, a line connection, and/or other electronic circuits. When the control unit 150 is implemented as (or implemented by) a microprocessor or similar hardware, the control unit 150 may be programmed and controlled by using software to perform the above-described functions and may be selectively driven by firmware and/or software. Also, the control unit 150 may be implemented by dedicated hardware or may be implemented by a combination of dedicated hardware for performing a function and a processor for performing another function (e.g., at least one programmed microprocessor and an associated circuit).

As described above, the transfer system 100 (or the manufacturing equipment of the display device) may transfer the light emitting elements SC from the first substrate 122 onto the second substrate 132 such that light emitting elements SC having the same light emission characteristic or similar light emission characteristics are gathered and located together. When light emitting elements SC having the same light emission characteristic or similar light emission characteristics are gathered and located in the display device 10 (see, e.g., FIG. 1), Mura (or Mura phenomenon) caused by a deviation in the light emission characteristic does not occur.

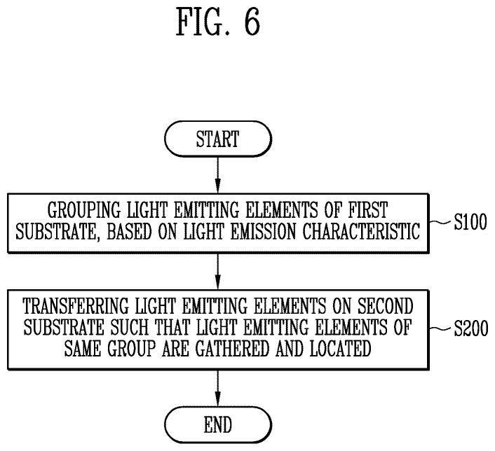

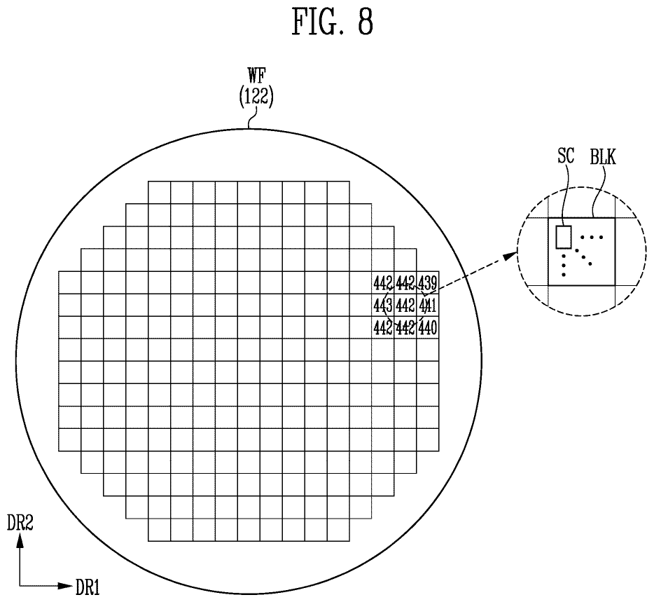

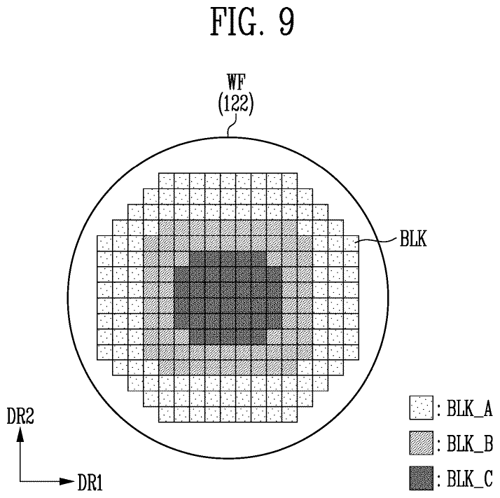

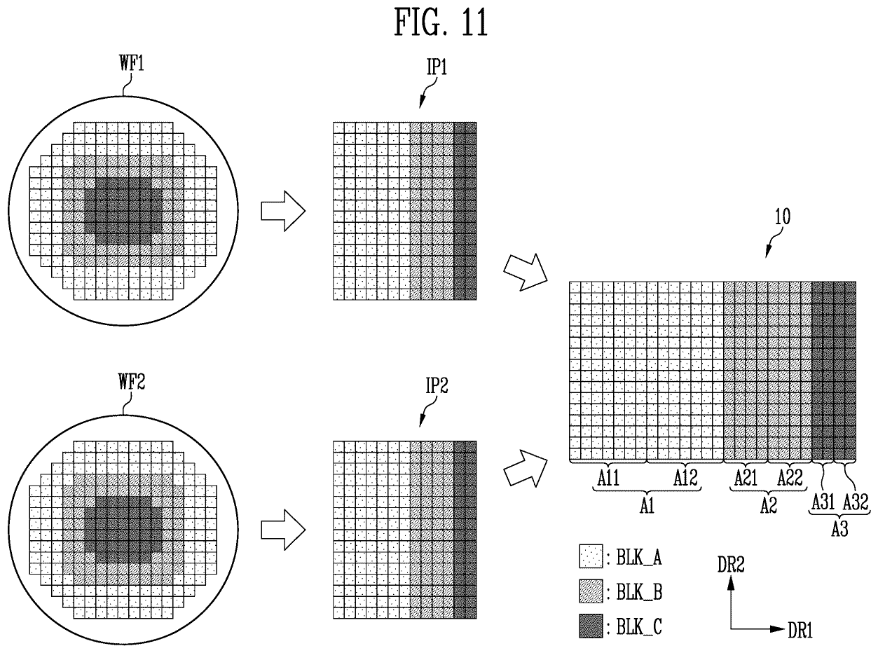

FIG. 6 is a flowchart describing a manufacturing method of a display device according to an embodiment of the present disclosure. FIG. 7 is an image illustrating an example of a light emission characteristic of light emitting elements of a first substrate. FIG. 8 is a diagram illustrating an example in which light emitting elements of a first substrate are divided into blocks. FIG. 9 is a diagram illustrating an example in which the blocks shown in FIG. 8 are grouped. FIG. 10 is a diagram illustrating an example in which the light emitting elements of the first substrate are mapped to a second substrate in a block unit. FIG. 11 is a diagram illustrating an example in which light emitting elements are transferred in a block unit.

First, referring to FIGS. 5 and 6, the manufacturing method shown in FIG. 6 may be performed by using (or in) the manufacturing equipment shown in FIG. 5, for example, by using the transfer system 100.

The transfer system 100 (or the control unit 150) may group the light emitting elements SC formed on the first substrate 122 based on a light emission characteristic (S100). The first substrate 122 is a source substrate on which the light emitting elements SC are formed. Hereinafter, an embodiment in which the first substrate 122 is a wafer WF (see, e.g., FIG. 8) will be described as an example.

For example, the transfer system 100 (or the control unit 150) may group the light emitting elements SC by analyzing an image IMAGE1 shown in, for example, FIG. 7. The image IMAGE1 may be acquired by capturing an image of the wafer WF (or the first substrate 122) by using an image capturing device (e.g., a camera) independent from the transfer system 100 and may be provided to the transfer system 100 (or the control unit 150) from the image capturing device or an external device. In some embodiments, the transfer system 100 may include the image capturing device.

As shown in, for example, FIG. 7, the wavelength of light emitted from the light emitting elements SC on the wafer WF may vary at each position. For example, the light emitting elements SC may emit light in a blue wavelength band in a range of about 430 nm to about 455 nm. The image IMAGE1 shown in FIG. 7 is merely a schematic example for describing the light emission characteristic of the light emitting elements SC on the wafer WF, and the light emission characteristic of the light emitting elements SC on the wafer WF is not limited to that shown in FIG. 7.

Although the light emitting elements SC are concurrently (or simultaneously) manufactured on the same wafer WF through the same process, a minute difference in material mixture occurs at each position, for example, during deposition (e.g., epitaxial deposition) for manufacturing the light emitting elements SC, and the intensity, chromaticity, wavelength, and the like of light may vary for each position of the wafer WF due to a difference in energy level according to the difference in material mixture between the light emitting elements SC. For example, as shown in FIG. 7, a wavelength dispersion may occur across the wafer WF.

In an embodiment, as shown in, for example, FIG. 8, the transfer system 100 (or the control unit 150) may divide the light emitting elements SC on the wafer WF (or the first substrate 122) into a plurality of blocks BLK based on positions. Each of the blocks BLK may correspond to a transfer unit (or a transfer array, for example, an area in which light emitting elements are transferred with one laser emission or laser shot) in which light emitting elements are transferred at a time and may include at least one light emitting element. A size of the block BLK (or a number of light emitting elements transferred at a time) may be variously set by considering a specification of the transfer unit 110, a transfer time, and the like. However, the size of the block BLK is not limited.

In an embodiment, the transfer system 100 (or the control unit 150) may group the blocks BLK based on a light emission characteristic. The light emission characteristic may be an average wavelength of light emitted from light emitting elements SC in each block BLK. For example, each of numbers (e.g., 439, 440, 441,and 422) written in some blocks shown in FIG. 8 may refer to an average wavelength (nm) of light emitted from a corresponding block BLK. For example, the transfer system 100 (or the control unit 150) may calculate an average wavelength for each block from the image IMAGE1 shown in FIG. 7 and may group the blocks BLK based on the average wavelength.

For example, as shown in FIG. 9, the blocks BLK may be divided into three groups. An example will be described with reference to FIG. 7. A wavelength range of about 430 nm to about 442 nm may correspond to a first group, a wavelength range of about 443 nm to about 449 nm may correspond to a second group, and a wavelength range of about 450 nm to about 455 nm may correspond to a third group. That is, the blocks BLK may be graded (or grouped) according to wavelengths. Hereinafter, a block BLK included in the first group will be referred to as a first block BLK_A (or first group block), a block BLK included in the second group will be referred to as a second block BLK_B (or second group block), and a block BLK included in the third group will be referred to as a third block BLK_C (or third group block).

A difference in light emission characteristic between blocks BLK (or light emitting elements SC) included in the same group may be within about 3%, and blocks BLK (or light emitting elements SC) included in the same group may have the substantially same light emission characteristic or have substantially similar light emission characteristics. A reference for dividing or grading groups may be set (e.g., may be automatically set) by analyzing the image IMAGE1 shown in, for example, FIG. 7, but the present disclosure is not limited thereto. For example, the reference may be provided or input to the transfer system 100 (or the control unit 150) from the outside (e.g., by a user).

Referring back to FIGS. 5 and 6, the transfer system 100 may transfer the light emitting elements SC onto the second substrate 132 such that light emitting elements SC grouped as the same group are adjacent to each other (S200). The second substrate 132 may refer to a target substrate on which the light emitting elements SC are transferred. Hereinafter, although an embodiment in which the second substrate 132 is an interposer IP (see, e.g., FIG. 10) is described as an example, the present disclosure is not limited thereto.

In an embodiment, the transfer system 100 (or the control unit 150) may generate mapping information by mapping positions of blocks BLK (or light emitting elements SC) grouped as the same group on the first substrate 122 to positions at which the blocks BLK (or light emitting elements SC) are to be transferred on the second substrate 132 such that the blocks BLK (or light emitting elements SC) are located adjacent to each other on the second substrate 132.

For example, as shown in FIG. 10, the first block BLK_A of the wafer WF may be mapped to a first area AA1 of the interposer IP, the second block BLK_B of the wafer WF may be mapped to a second area AA2 of the interposer IP, and the third block BLK_C of the wafer WF may be mapped to a third area AA3 of the interposer IP. Accordingly, only the first block BLK_A may be transferred to the first area AA1 of the interposer IP, only the second block BLK_B may be transferred to the second area AA2 of the interposer IP, and only the third block BLK_C may be transferred to the third area AA3 of the interposer IP.

In an embodiment, the transfer system 100 (or the control unit 150) may generate mapping information such that the light emission characteristic gradually changes (or varies) along the first direction DR1 on the second substrate 132. Blocks

BLK (or light emitting elements SC) arranged along the second direction DR2 perpendicular to the first direction DR1 on the second substrate 132 may have substantially the same light emission characteristic. According to the mapping information, the transfer system 100 (or the transfer unit 110) may transfer the blocks BLK (or light emitting elements SC) such that the light emission characteristic gradually changes (or varies) along the first direction DR1 on the second substrate 132.

For example, as shown in FIG. 10, the interposer IP (or the second substrate 132) may have the first area AA1, the second area AA2, and the third area AA3, which are sequentially arranged along the first direction DR1, and the first block BLK_A, the second block BLK_B, and the third block BLK_C may be sequentially arranged along the first direction DR1 on the interposer IP (or the second substrate 132) to correspond to the first area AA1, the second area AA2, and the third area AA3.

When the area of the display device 10 (see, e.g., FIG. 1) is relatively small, a transfer process may be performed only once. However, when the area of the display device 10 (see, e.g., FIG. 1) is relatively large, the transfer process may be performed at least twice.

Referring to FIGS. 8 to 11, light emitting elements SC may be transferred to the display device 10 (or a third substrate) via interposers IP1 and IP2 from wafers WF1 and WF2.

For example, the transfer system 100 (see, e.g., FIG. 5) may transfer light emitting elements SC of a first wafer WF1 on a first interposer IP1 in a block unit and may transfer light emitting elements SC of a second wafer WF2 on a second interposer IP2 in a block unit. Thereafter, the transfer system 100 may transfer the light emitting elements SC of the first interposer IP1 and the light emitting elements SC of the second interposer IP2 to the display device 10 (or the display panel).

For example, when the display device 10 has a first area A1, a second area A2, and a third area A3, which are sequentially arranged along the first direction DR1, first blocks BLK_A of the first and second wafers WF1 and WF2 may be transferred to the first area A1, second blocks BLK_B of the first and second wafers WF1 and WF2 may be transferred to the second area A2, and third blocks BLK_C of the first and second wafers WF1 and WF2 may be transferred to the third area A3. For example, the first block BLK_A of the first wafer WF1 may be transferred to an eleventh area A11 in the first area A1, and the first block BLK_A of the second wafer WF2 may be transferred to a twelfth area A12 in the first area A1. Similarly, the second block BLK_B of the first wafer WF1 may be transferred to a twenty-first area A21 in the second area A2, the second block BLK_B of the second wafer WF2 may be transferred to a twenty-second area A22 in the second area A2, the third block BLK_C of the first wafer WF1 may be transferred to a thirty-first area A31 in the third area A3, and the third block BLK_C of the second wafer WF2 may be transferred to a thirty-second area A32 in the third area A3. However, the present disclosure is not limited thereto. For example, the first block BLK_A of the first wafer WF1 may be transferred to the twelfth area A12 in the first area A1, and the first block BLK_A of the second wafer WF2 may be transferred to the eleventh area A11 in the first area A1. The transfer system 100 (or the control unit 150) may generate mapping information for transferring light emitting elements SC to the display device 10 from the interposers IP1 and IP2.

FIG. 11 illustrates an embodiment in which two wafers WF1 and WF2 and two interposers IP1 and IP2 are used in one display device 10. However, the number of wafers and/or the number of interposers are/is not limited thereto.

As described above, the light emitting elements SC (or blocks BLK) can be transferred to or disposed in the interposer IP or the display device 10 such that the light emission characteristic (e.g., the wavelength) gradually changes (or varies) along the first direction DR1. Thus, although a deviation occurs in the light emission characteristic (e.g., the wavelength) of the light emitting elements SC of the wafer WF (or the first substrate 122), Mura caused by the deviation in the light emission characteristic is not visible in the display device 10. In addition, Mura correction can be readily performed for each area of the display device 10.

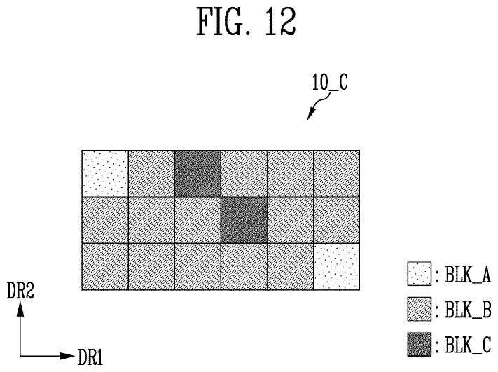

FIG. 12 is a diagram illustrating a display device according to a comparative example.

Referring to FIGS. 7 and 12, a display device 10_C was manufactured by transferring light emitting elements SC in a block unit from a wafer WF in an arbitrary order (e.g., randomly) without considering a light emission characteristic of the light emitting elements SC. Accordingly, first, second, and third blocks BLK_A, BLK_B, and BLK_C (e.g., light emitting elements SC in different wavelength ranges) may be irregularly arranged in the display device 10_C, and Mura may occur in the display device 10_C (or in an image displayed in the display device 10_C), or a grid pattern corresponding to a block size may be visible. To eliminate the Mura, Mura correction (e.g., correction for a luminance or color sense) may be performed. However, the Mura in the display device 10_C is irregular, and therefore, the Mura correction may be difficult or complicated.

In the manufacturing method of the display device according to embodiments of the present disclosure, the light emitting elements SC are transferred or disposed such that the light emission characteristic gradually changes (or varies) along the first direction DR1 in the display device 10 so that Mura can be eliminated or Mura correction (or image quality correction) can be readily performed.

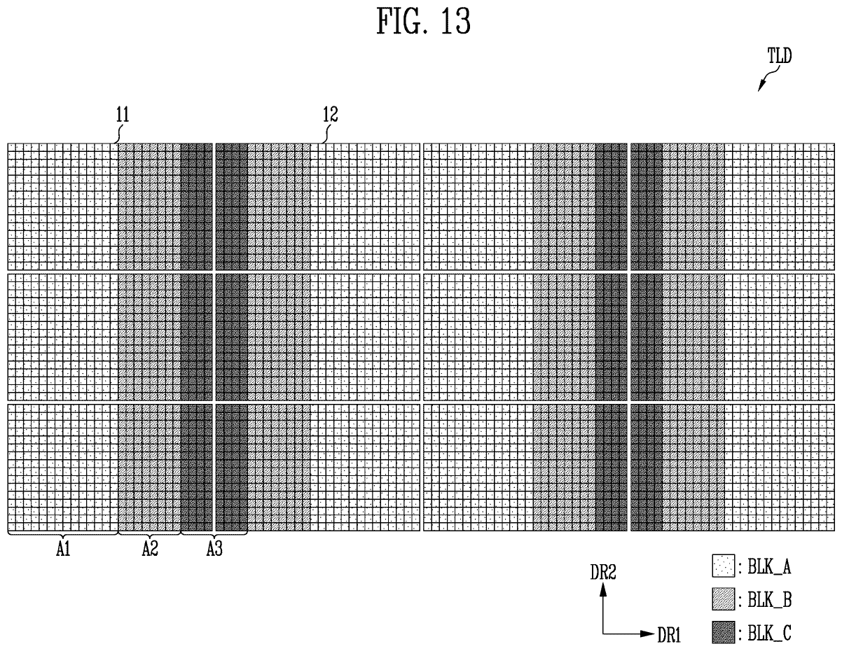

FIG. 13 is a plan view illustrating a display device according to an embodiment of the present disclosure.

Referring to FIGS. 4 and 13, a tiled display device TLD may include a plurality of display devices. For example, as shown in FIG. 13, the tiled display device TLD may include display devices arranged in a matrix form having three rows and four columns. Each of the display devices may be substantially identical to the display device 10 shown in, for example, FIG. 11. In a manufacturing method of the display device, the tiled display device TLD may be manufactured by successively connecting the display devices (e.g., the display devices manufactured through the processes described with reference to FIGS. 6 to 11) to each other.

The tiled display device TLD may have a first area A1, a second area A2, and a third area A3, which are sequentially arranged along the first direction DR1. A first block BLK_A may be disposed in the first area A1, a second block BLK_B may be disposed in the second area A2, and a third block BLK_C may be disposed in the third area A3. That is, even in the tiled display device TLD, light emitting elements may be arranged such that a light emission characteristic (e.g., a wavelength) gradually changes (or varies) along the first direction DR1.

In an embodiment, the display devices of the tiled display device TLD may be arranged such that light emitting elements having the same light emission characteristic are disposed adjacent to each other between the display devices.

For example, a first display device 11 (or a first sub-panel) and a second display device 12 (or a second sub-panel) from among the display devices may be located adjacent to each other in the first direction DR1, and light emitting elements SC (see, e.g., FIG. 8) having the same light emission characteristic may be disposed at a first edge of the first display device 11 and a second edge of the second display device 12, which face each other or are connected to each other. For example, the third block BLK_C (or light emitting elements SC included in the third block BLK_C) may be disposed in one area of the first display device 11 and one area of the second display device 12, which are included in the third area A3 and face each other. For example, in relation to the light emission characteristic, an arrangement order of light emitting elements SC in the second display device 12 may be opposite to an arrangement order of light emitting elements SC in the first display device 11. Mura correction (or image quality correction) for the tiled display device TLD can be more readily performed.

In a similar manner, the display devices in the tiled display device TLD may be arranged such that light emitting elements SC having similar light emission characteristics are located adjacent to each other between the display devices.

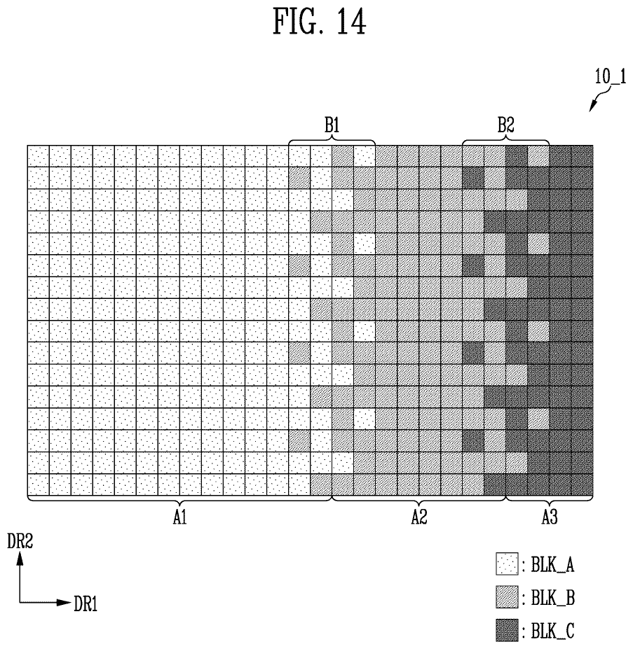

FIG. 14 is a plan view illustrating a display device according to an embodiment of the present disclosure.

Referring to FIGS. 11 and 14, the display device 10_1 shown in FIG. 14 is substantially identical or similar to the display device 10 shown in FIG. 11 except for boundary areas B1 and B2, and therefore, overlapping descriptions will not be repeated.

A first block BLK_A (e.g., light emitting elements included in the first block BLK_A) and a second block BLK_B (e.g., light emitting elements included in the second block BLK_B) may be mixed and disposed in a first boundary area B1 between a first area A1 and a second area A2. For example, three first blocks BLK_A and one second block BLK_B may be alternately disposed along the second direction DR2 in the first boundary area B1 of the first area A1. Similarly, three second blocks BLK_B and one first block BLK_A may be alternately disposed along the second direction DR2 in the first boundary area B1 of the second area A2. For example, in a manufacturing method of the display device, the first block BLK_A and the second block BLK_B may be mixed and disposed in the first boundary area B1 by using a dithering technique.

Accordingly, viewing (or visibility of) a boundary line between the first area A1 and the second area A2, which have different light emission characteristics, can be prevented or reduced.

Similar to the first boundary area B1, the second block BLK_B (e.g., the light emitting elements included in the second block BLK_B) and a third block BLK_C (e.g., light emitting elements included in the third block BLK_C) may be mixed and disposed in a second boundary area B2 between the second area A2 and a third area A3.

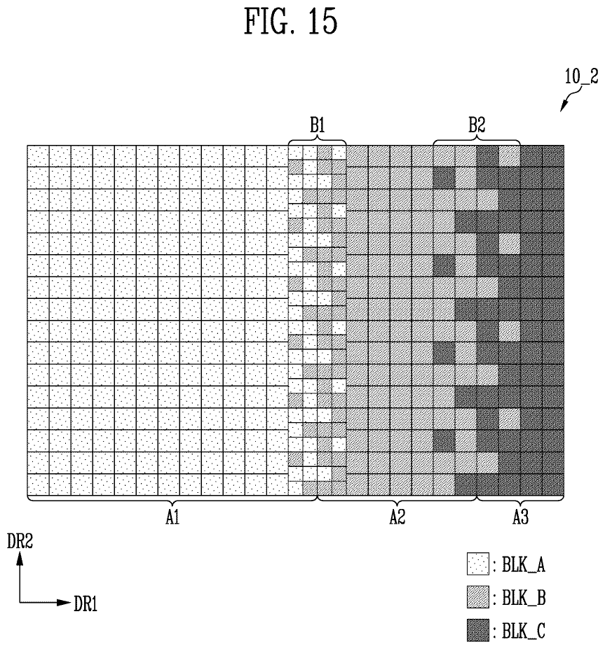

FIG. 15 is a plan view illustrating a display device according to an embodiment of the present disclosure.

Referring to FIGS. 11, 14, and 15, the display device 10_2 shown in FIG. 15 is substantially identical or similar to the display device 10_1 shown in FIG. 14 except for a first boundary area B1, and therefore, overlapping descriptions will not be repeated.

A size of a block in the first boundary area B1 between a first area A1 and a second area A2 may be different from a size of a block in the other area (e.g., the other area of the display device 10_2 except for the first boundary area B1). For example, the size of the block in the first boundary area B1 may be smaller than the size of the block in the other area. For example, in a manufacturing method of the display device, light emitting elements may be transferred to the other area of the display device 10_2 except for the first boundary area B1 in a first block unit having a first size, and light emitting elements may be transferred to the first boundary area B1 in a second block unit having a second size smaller than the first size.

As the size of the block (or the size of a transfer array) is reduced, a probability that grid Mura will be viewed (or may be visible) may be reduced, but the time required to transfer may be increased. Therefore, in the manufacturing method of the display device, transfer may be performed in a relatively small block unit in the first boundary area B1 in which light emitting elements having different light emission characteristics are mixed together, and transfer may be performed in a relatively large block unit in the other area(s) in which the same light emitting elements are located. Thus, Mura is not viewed (or may be visible) while the time required in a transfer process is shortened.

In FIG. 15, an embodiment in which only the size of the block in the first boundary area B1 is small is illustrated, but the present disclosure is not limited thereto. For example, a size of a block in a second boundary area B2 may be smaller than a size of a block in the other area and may be equal to the size of the block in the first boundary area B1.

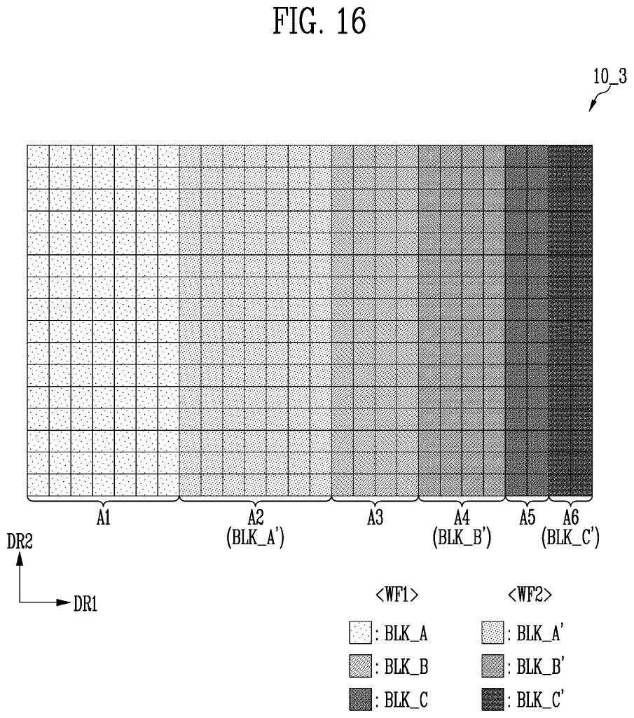

FIG. 16 is a plan view illustrating a display device according to an embodiment of the present disclosure.

Referring to FIGS. 11 and 16, the first and second wafers WF1 and WF2 include the same blocks BLK_A to BLK_C as shown in FIG. 11, and a second wafer WF2 may include blocks BLK_A′ to BLK_C′ different from blocks BLK_A to BLK_C of a first wafer WF1 shown in FIG. 16. For example, due to a minute difference between process conditions, material mixing ratios, or the like of the first wafer WF1 and the second wafer WF2, the entire light emission characteristic (or light emission characteristic for each block) of the second wafer WF2 may be different from a light emission characteristic of the first wafer WF1, and blocks of the second wafer WF2 may be grouped differently from blocks of the first wafer WF1.

The blocks (or light emitting elements) of the first and second wafers WF1 and WF2 may be transferred to the display device 10_3 such that the light emission characteristic gradually changes (or varies) along the first direction DR1 in the display device 10_3.

For example, an average wavelength as the light emission characteristic may become larger or longer in an order of a first block BLK_A of the first wafer WF1, a first block BLK_A′ of the second wafer WF2, a second block BLK_B of the first wafer WF1, a second block BLK_B′ of the second wafer WF2, a third block BLK_C of the first wafer WF1, and a third block BLK_C′ of the second wafer WF2.

When the display device 10_3 has areas A1 to A6 sequentially arranged along the first direction DR1, the first block BLK_A of the first wafer WF1 may be transferred to a first area A1, the first block BLK_A′ of the second wafer WF2 may be transferred to a second area A2, the second block BLK_B of the first wafer WF1 may be transferred to a third area A3, the second block BLK_B′ of the second wafer WF2 may be transferred to a fourth area A4, the third block BLK_C of the first wafer WF1 may be transferred to a fifth area A5, and the third block BLK_C′ of the second wafer WF2 may be transferred to a sixth area A6.

Even when the display device 10_3 is manufactured by using at least two wafers WF1 and WF2 having different light emission characteristics, Mura caused by a deviation in light emission characteristic is not visible. In addition, Mura correction can be readily performed for each area of the display device 10_3.

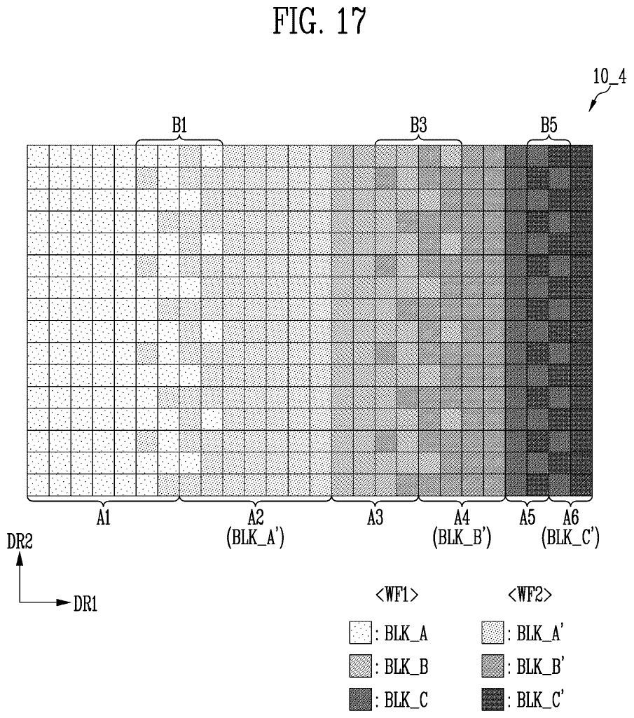

FIG. 17 is a plan view illustrating a display device according to an embodiment of the present disclosure.

Referring to FIGS. 16 and 17, the display device 10_4 shown in FIG. 17 is substantially identical or similar to the display device 10_3 shown in FIG. 16 except for boundary areas B1, B3, and B5, and therefore, overlapping descriptions will not be repeated.

A first block BLK_A (e.g., light emitting elements included therein) of a first wafer WF1 and a first block BLK_A′ (e.g., light emitting elements included therein) of a second wafer WF2 may be mixed and disposed in a first boundary area B1 between a first area A1 and a second area A2.

Similarly, a second block BLK_B (e.g., light emitting elements included therein) of the first wafer WF1 and a second block BLK_B′ (e.g., light emitting elements included therein) of the second wafer WF2 may be mixed and disposed in a third boundary area B3 between a third area A3 and a fourth area A4.

A third block BLK_C (e.g., light emitting elements included therein) of the first wafer WF1 and a third block BLK_C′ (e.g., light emitting elements included therein) of the second wafer WF2 may be mixed and disposed in a fifth boundary area B5 between a fifth area A5 and a sixth area A6.

Viewing (or visibility of) a boundary line between the first area A1 and the second area A2, a boundary line between the third area A3 and the fourth area A4, and a boundary line between the fifth area A5 and the sixth area A6 can be prevented or reduced.

In some embodiments, the first block BLK_A′ (e.g., the light emitting elements included therein) of the second wafer WF2 and the second block BLK_B (e.g., the light emitting elements included therein) of the first wafer WF1 may be mixed and disposed in a boundary area between the second area A2 and the third area A3. Similarly, the second block BLK_B′ (e.g., the light emitting elements included therein) of the second wafer WF2 and the third block BLK_C (e.g., the light emitting elements included therein) of the first wafer WF1 may be mixed and disposed in a boundary area between the fourth area A4 and the fifth area A5.

The embodiment shown in FIG. 15 may be applied to FIG. 17.

In addition, the embodiments shown in FIGS. 14 to 17 may be applied to the tiled display device TLD shown in FIG. 13. In other words, the tiled display device TLD shown in FIG. 13 may include the display devices 10_1 to 10_4 shown in FIGS. 14 to 17.

In the manufacturing method and the manufacturing equipment of the display device according to embodiments of the present disclosure, light emitting elements may be transferred from the first substrate onto the second substrate such that light emitting elements having the same light emission characteristic (e.g., the same wavelength) or having similar light emission characteristics are gathered and located. Also, in the manufacturing method and the manufacturing equipment of the display device according to embodiments of the present disclosure, light emitting elements may be transferred onto the second substrate such that a light emission characteristic gradually changes (or varies) along the first direction. Thus, although a deviation occurs in a light emission characteristic of the light emitting elements of the first substrate, Mura caused by a deviation in light emission characteristic is not visible in the second substrate and the display device including the same. In addition, Mura correction can be readily performed for each area of the display device.

Example embodiments of the present disclosure have been disclosed herein, and although specific terms are employed, they are used and are to be interpreted in a generic and descriptive sense and not for purpose of limitation. In some instances, as would be apparent to one of ordinary skill in the art as of the filing of the present application, features, characteristics, and/or elements described in connection with one embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims and their equivalents.

1 What is claimed is:

1. A method of manufacturing a display device, the method comprising:
grouping light emitting elements formed on a first substrate based on a light emission characteristic; and
transferring the light emitting elements onto a second substrate such that the light emitting elements grouped as the same group are located adjacent to each other.

2. The method of claim 1, wherein the grouping of the light emitting elements comprises:
dividing the light emitting elements on the first substrate into a plurality of blocks based on positions; and
grouping the blocks based on the light emission characteristic, and
wherein the transferring of the light emitting elements onto the second substrate comprises transferring the light emitting elements in a block unit onto the second substrate such that blocks included in the same group from among the blocks are located adjacent to each other.

3. The method of claim 2, wherein the light emission characteristic is an average wavelength of light emitted from light emitting elements in each of the blocks.

4. The method of claim 2, wherein, in the transferring of the light emitting elements onto the second substrate, the light emitting elements are transferred such as the light emission characteristic gradually changes along a first direction on the second substrate.

5. The method of claim 4, wherein light emitting elements arranged along a second direction perpendicular to the first direction on the second substrate have the same light emission characteristic.

6. The method of claim 4, wherein the second substrate has a first area, a second area, and a third area that are sequentially arranged along the first direction, and wherein the blocks grouped as a first group are transferred to the first area, the blocks grouped as a second group are transferred to the second area, and the blocks grouped as a third group are transferred to the third area.

7. The method of claim 1, further comprising successively connecting a first sub-panel and a second sub-panel, each of which comprises the light emitting elements on the second substrate, wherein the light emitting elements having the same light emission characteristic are at a first edge of the first sub-panel and a second edge of the second sub-panel, which are connected to each other.

8. The method of claim 1, wherein groups into which the light emitting elements are grouped comprise a first group and a second group,
wherein the second substrate has a first area and a second area, which are sequentially arranged along a first direction,
wherein the light emitting elements in the first group are arranged in the first area of the second substrate,
wherein the light emitting elements in the second group are arranged in the second area of the second substrate, and
wherein the light emitting elements in the first group and the second group are mixed and arranged in a boundary area between the first area and the second area.

9. The method of claim 8, wherein the transferring of the light emitting elements on the second substrate comprises:
transferring the light emitting elements onto the first and second areas of the second substrate in a first block unit having a first size; and
transferring the light emitting elements onto the boundary area of the second substrate in a second block unit having a second size smaller than the first size.

10. The method of claim 1, further comprising transferring light emitting elements formed on a third substrate different from the first substrate onto the second substrate such that the light emitting elements having similar light emission characteristics are located adjacent to each other.

11. An equipment for manufacturing a display device, the equipment comprising:
a control unit configured to group light emitting elements formed on a first substrate based on a light emission characteristic and to generate mapping information by mapping positions of the light emitting elements on the first substrate to positions at which the light emitting elements are to be transferred onto a second substrate such that the light emitting elements grouped as the same group are located adjacent to each other on the second substrate; and
a transfer unit configured to transfer the light emitting elements from the first substrate onto the second substrate based on the mapping information.

12. The equipment of claim 11, wherein the control unit is configured to divide the light emitting elements on the first substrate into a plurality of blocks based on positions, to groups the blocks based on the light emission characteristic, and to generate the mapping information such that the blocks grouped as the same group are located adjacent to each other.

13. The equipment of claim 12, wherein the light emission characteristic is an average wavelength of light emitted from light emitting elements in each of the blocks.

14. The equipment of claim 12, wherein the control unit is configured to generate the mapping information such that the light emission characteristic gradually changes along a first direction on the second substrate, and
wherein light emitting elements arranged along a second direction perpendicular to the first direction on the second substrate have the same light emission characteristic.

15. The equipment of claim 14, wherein the second substrate has a first area, a second area, and a third area, which are sequentially arranged along the first direction, and
wherein the transfer unit is configured to transfer the blocks grouped as a first group to the first area, to transfer the blocks grouped as a second group to the second area, and to transfer the blocks grouped as a third group to the third area.

16. A display device comprising:
light emitting elements arranged on a substrate,
wherein the light emitting elements are grouped based on a light emission characteristic, and
wherein light emitting elements grouped as the same group are located adjacent to each other.

17. The display device of claim 16, wherein the light emission characteristic of the light emitting elements gradually changes along a first direction, and
wherein light emitting elements arranged along a second direction perpendicular to the first direction have the same light emission characteristic.

18. The display device of claim 17, wherein the substrate has a first area, a second area, and a third area, which are sequentially arranged along the first direction,
wherein the light emitting elements having a first light emission characteristic are arranged in the first area,
wherein the light emitting elements having a second light emission characteristic are arranged in the second area, and
wherein the light emitting elements having a third light emission characteristic are arranged in the third area, and
wherein the first light emission characteristic, the second light emission characteristic, and the third light emission characteristic are different from one another.

19. The display device of claim 18, wherein the light emitting elements having the first light emission characteristic and the light emitting elements having the second light emission characteristic are mixed and arranged in a boundary area between the first area and the second area.

20. The display device of claim 16, further comprising a first sub-panel and a second sub-panel, each comprising the light emitting elements on the substrate, the first sub-panel and the second sub-panel being successively connected to each other,
wherein the light emitting elements having the same light emission characteristic are arranged at a first edge of the first sub-panel and a second edge of the second sub-panel, which are connected to each other.
